(19) United States
(12) Patent Application Publication
(10) Pub. No.: US 2018/0169697 A1
(43) Pub. Date: Jun. 21, 2018

(54) BARRIER FILMS, VACUUM INSULATION PANELS AND MOISTURE BARRIER BAGS EMPLOYING SAME

(71) Applicant: 3M INNOVATIVE PROPERTIES COMPANY, St. Paul, MN (US)

(72) Inventors: Christopher A. Merton, St. Louis Park, MN (US); Ta-Hua Yu, Woodbury, MN (US); Christopher S. Lyons, St. Paul, MN (US); Kam Poi Chia, Singapore (SG); Brent Beamer, Cary, NC (US); Cedric Bedoya, Woodbury, MN (US); Paul T. Engen, River Falls, WI (US); Amy Preszler Prince, Woodbury, MN (US)

(21) Appl. No.: 15/735,293

(22) PCT Filed: Jun. 9, 2016
(86) PCT No.: PCT/US2016/036644

§ 371 Date: Dec. 11, 2017

Related U.S. Application Data
(60) Provisional application No. 62/180,321, filed on Jun. 16, 2015.

(51) Int. Cl. B05D 1/00; B05D 3/14; C23C 14/20; C23C 14/08; C23C 14/34

(52) U.S. Cl. CPC B05D 1/60; B05D 3/144; C23C 14/34; C23C 14/081; C23C 14/205

(57) ABSTRACT

There is provided a barrier film having a substrate, a low thermal conductivity organic layer and an inorganic stack. The inorganic stack will include a low thermal conductivity non-metallic inorganic material layer and a high thermal conductivity metallic material layer.

### FIELD

The present disclosure relates to barrier films. The present disclosure further provides articles comprising vacuum insulation panels or static shielding moisture barrier bags employing these barrier films.

### BACKGROUND

Inorganic or hybrid inorganic/organic layers have been used in thin films for electrical, packaging and decorative applications. For example, multilayer stacks of inorganic or hybrid inorganic/organic layers can be used to make barrier films resistant to moisture permeation. Multilayer barrier films have also been developed to protect sensitive materials from damage due to water vapor. The water sensitive materials can be electronic components such as organic, inorganic, and hybrid organic/inorganic semiconductor devices.

A vacuum insulation panel (VIP) is a form of thermal insulation consisting of a nearly gas-tight envelope surrounding a core, from which the air has been evacuated. VIP can be formed from barrier films. VIP is used in, e.g. appliances and building construction to provide better insulation performance than conventional insulation materials. Since the leakage of air into the envelope would eventually degrade the insulation value of a VIP, known designs use foil laminated with heat-sealable material as the envelope to provide a gas barrier. However, the foil decreases the overall VIP thermal insulation performance. There exists a need for better barrier films or envelope films formed from these barrier films.

Moisture barrier bags are useful for packaging electronic components. Moisture barrier bags can be formed from barrier films and function as a barrier against moisture vapor and oxygen to protect the electronic component from degradation while it is being stored. While the technology of the prior art may be useful, other constructions for moisture barrier bags useful for packaging electronic components are desired.

### SUMMARY

The present disclosure provides a barrier film with exceptional utility for use, for example, as the envelope for vacuum insulation panels and static shielding moisture barrier bags. It combines moisture permeation and puncture resistance, electromagnetic interference (EMI) shielding, static shielding and semi-transparence.

Thus, in one aspect, the present disclosure provides a barrier film comprising: a substrate having two opposing major surfaces; a first layer in direct contact with one of the opposing major surfaces of the substrate, wherein the first layer is an inorganic stack or a low thermal conductivity organic layer or; and a second layer in direct contact with the first layer, wherein the second layer is an inorganic stack or a low thermal conductivity organic layer, and wherein the second layer is not the same as that selected in the first layer; wherein the inorganic stack comprises a low thermal conductivity non-metallic inorganic material layer and a high electrical conductivity metallic material layer having a high thermal resistance in the plane of the high electrical conductivity metallic material layer; wherein the barrier film is semitransparent.

In another aspect, the present disclosure provides an article comprising a vacuum insulation panel envelope comprising: a substrate having two opposing major surfaces; a first layer in direct contact with one of the opposing major surfaces of the substrate, wherein the first layer is an inorganic stack or a low thermal conductivity organic layer or; and a second layer in direct contact with the first layer, wherein the second layer is an inorganic stack or a low thermal conductivity organic layer, and wherein the second layer is not the same as that selected in the first layer; wherein the inorganic stack comprises a low thermal conductivity non-metallic inorganic material layer and a high electrical conductivity metallic material layer having a high thermal resistance in the plane of the high electrical conductivity metallic material layer.

In another aspect, the present disclosure provides an article comprising a moisture barrier bag comprising: a substrate having two opposing major surfaces; a first layer in direct contact with one of the opposing major surfaces of the substrate, wherein the first layer is an inorganic stack or a low thermal conductivity organic layer or; and a second layer in direct contact with the first layer, wherein the second layer is an inorganic stack or a low thermal conductivity organic layer, and wherein the second layer is not the same as that selected in the first layer; wherein the inorganic stack comprises a low thermal conductivity non-metallic inorganic material layer and a high electrical conductivity metallic material layer having a high thermal resistance in the plane of the high electrical conductivity metallic material layer; wherein the barrier film is semitransparent.

Various aspects and advantages of exemplary embodiments of the present disclosure have been summarized. The above Summary is not intended to describe each illustrated embodiment or every implementation of the present disclosure. Further features and advantages are disclosed in the embodiments that follow. The Drawings and the Detailed Description that follow more particularly exemplify certain embodiments using the principles disclosed herein.

### Definitions

For the following defined terms, these definitions shall be applied for the entire Specification, including the claims, unless a different definition is provided in the claims or elsewhere in the Specification based upon a specific reference to a modification of a term used in the following definitions:

The terms “about” or “approximately” with reference to a numerical value or a shape means+/−five percent of the numerical value or property or characteristic, but also expressly includes any narrow range within the +/−five percent of the numerical value or property or characteristic as well as the exact numerical value. For example, a temperature of “about” 100° C. refers to a temperature from 95° C. to 105° C., but also expressly includes any narrower range of temperature or even a single temperature within that range, including, for example, a temperature of exactly 100° C.

The terms “a”, “an”, and “the” include plural referents unless the content clearly dictates otherwise. Thus, for example, reference to a material containing “a compound” includes a mixture of two or more compounds.

The term “layer” refers to any material or combination of materials on or overlaying a substrate.

The term “stack” refers to an arrangement where a particular layer is placed on at least one other layer but direct contact of the two layers is not necessary and there could be an intervening layer between the two layers.

Words of orientation such as “atop, “on,” “covering,” “uppermost,” “overlaying,” “underlying” and the like for describing the location of various layers, refer to the relative position of a layer with respect to a horizontally-disposed, upwardly-facing substrate. It is not intended that the substrate, layers or articles encompassing the substrate and layers, should have any particular orientation in space during or after manufacture.

The term “separated by” to describe the position of a layer with respect to another layer and the substrate, or two other layers, means that the described layer is between, but not necessarily contiguous with, the other layer(s) and/or substrate.

The term “(co)polymer” or “(co)polymeric” includes homopolymers and copolymers, as well as homopolymers or copolymers that may be formed in a miscible blend, e.g., by coextrusion or by reaction, including, e.g., transesterification. The term “copolymer” includes random, block, graft, and star copolymers.

The term “semitransparent” refers to having a 20% to 80% average visible light transmission, which is measured as the average value of the % light transmitted from 400 nm to 700 nm by a transmission reflection densitometer.

### BRIEF DESCRIPTION OF THE DRAWINGS

The disclosure may be more completely understood in consideration of the following detailed description of various embodiments of the disclosure in connection with the accompanying figures, in which:

FIG. 1 is a side view of an exemplary barrier film according to the present invention.

FIG. 2 is a front view of an exemplary vacuum insulation panel employing the barrier film of FIG. 1.

While the above-identified drawings, which may not be drawn to scale, set forth various embodiments of the present disclosure, other embodiments are also contemplated, as noted in the Detailed Description. In all cases, this disclosure describes the presently disclosed invention by way of representation of exemplary embodiments and not by express limitations. It should be understood that numerous other modifications and embodiments can be devised by those skilled in the art, which fall within the scope and spirit of this disclosure.

### DETAILED DESCRIPTION

Before any embodiments of the present disclosure are explained in detail, it is understood that the invention is not limited in its application to the details of use, construction, and the arrangement of components set forth in the following description. The invention is capable of other embodiments and of being practiced or of being carried out in various ways that will become apparent to a person of ordinary skill in the art upon reading the present disclosure. Also, it is understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. It is understood that other embodiments may be utilized and structural or logical changes may be made without departing from the scope of the present disclosure.

As used in this Specification, the recitation of numerical ranges by endpoints includes all numbers subsumed within that range (e.g. 1 to 5 includes 1, 1.5, 2, 2.75, 3, 3.8, 4, and 5, and the like).

Unless otherwise indicated, all numbers expressing quantities or ingredients, measurement of properties and so forth used in the Specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

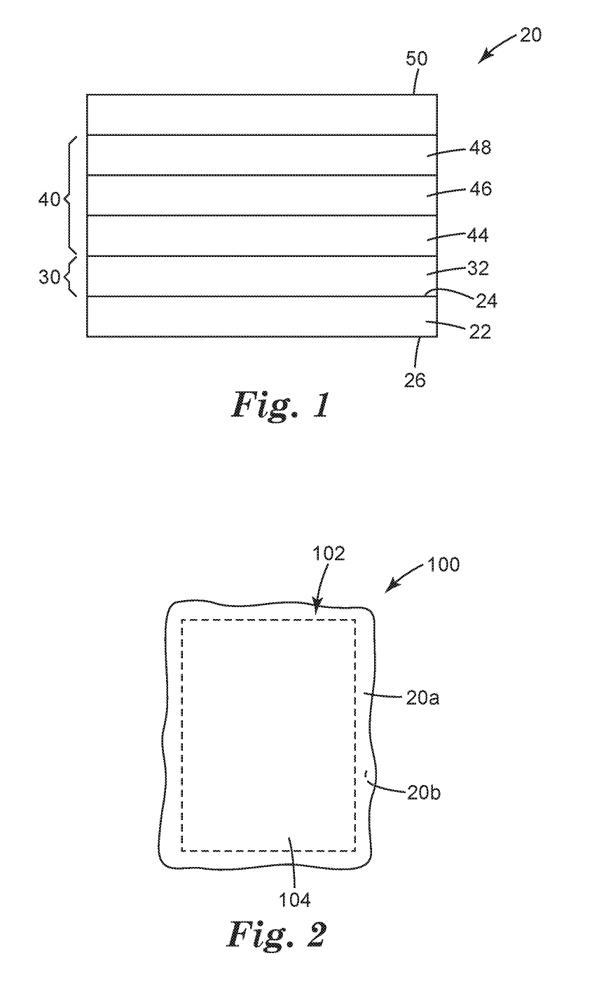

The present disclosure provides barrier films, VIP envelopes formed from these barrier films, VIPs comprising these envelopes, and moisture barrier bags formed from these barrier films. Referring now to FIG. 1, an exemplary barrier film 20 according to the present disclosure is illustrated. Barrier film 20 includes substrate 22 which has first 24 and second 26 major surfaces. In direct contact with the first major surface 24 of the substrate 22 is first layer 30, which is in turn in contact with second layer 40. The layer to be described below as first layer 30 and the layer to be described below as second layer 40 may actually be applied in either order to substrate 22 and still achieve suitable barrier properties, and either order is considered within the scope of the present disclosure.

First layer 30 in some embodiments, such as the depicted embodiment, is a low thermal conductivity organic layer 32. Additionally, good flexibility, toughness, and adhesion to the selected substrate are considered desirable. The low thermal conductivity organic layer 32 may be prepared by conventional coating methods such as roll coating (e.g., gravure roll coating) or spray coating (e.g., electrostatic spray coating) the monomer, and then crosslinking by using, e.g., ultraviolet light radiation. The low thermal conductivity organic layer 32 may also be prepared by flash evaporation of the monomer, vapor deposition, followed by crosslinking, as described in the following U.S. Pat. No. 4,842,893 (Yializis et al.); U.S. Pat. No. 4,954,371 (Yializis); U.S. Pat. No. 5,032,461 (Shaw et al.); U.S. Pat. No. 5,440,446 (Shaw et al.); U.S. Pat. No. 5,725,909 (Shaw et al.); U.S. Pat. No. 6,231,939 (Shaw et al.); U.S. Pat. No. 6,045,864 (Lyons et al.); U.S. Pat. No. 6,224,948 (Affinito), and U.S. Pat. No. 8,658,248 (Anderson et al.), all of which are herein incorporated by reference.

Second layer 40 in some embodiments, such as the depicted embodiment, is an inorganic stack (collectively 44, 46, and 48 in the depicted embodiment). This inorganic stack includes a low thermal conductivity non-metallic inorganic material layer 44 and a high electrical conductivity metallic material layer 46. Low thermal conductivity non-metallic inorganic material layer 44 and high electrical conductivity metallic material layer 46 may actually be applied in either order to first layer 30 and still achieve suitable barrier properties, and either order is considered within the scope of the present disclosure. Low thermal conductivity non-metallic inorganic material layer 44 preferably has a thermal conductivity of no more than 1, 0.5, 0.2 or even 0.015 W/(cm·K).

High electrical conductivity metallic material layer 46 can include a high electrical conductivity metallic material, which preferably has a electrical conductivity of more than 1×10⁷, more than 1.5×10⁷, more than 2×10⁷, more than 3×10⁷, more than 4×10⁷, or more than 5×10⁷ Siemens/m. Another property useful in a suitable high electricalconductivity metallic material layer 46 is a high thermal resistance in the plane of the layer. For example, high electrical conductivity metallic material layer 46 have a thermal resistance more than 1000, more than 2.5×10⁴ or more than 5×10⁵ Kelvin/W for a 1 cm×1 cm area.

In some depicted embodiments, an optional second low thermal conductivity non-metallic inorganic material layer 48 is present to provide desirable physical properties. Such layers are conveniently applied by sputtering, and a thickness between about 10 and 50 nm is considered convenient, with approximately 20 nm in thickness being considered particularly suitable.

Some embodiments, such as the depicted embodiment further include an optional low thermal conductivity organic layer 50 applied to the second layer 40 on the side away from the substrate 22. Such a layer may be employed to physically protect the non-metallic inorganic material layer 44. Some embodiments may include additional layers in order to achieve desirable properties. For example, if additional barrier properties are deemed desirable, an additional layer of non-metallic inorganic material may optionally be applied, including, e.g. above the protective second polymer layer. The additional layer of non-metallic inorganic material, can, for example provide an enhancing interfacial adhesion for lamination to another substrate.

Referring now to FIG. 2, a front view of a completed vacuum insulation panel 100 employing the barrier film of FIG. 1 as a vacuum insulation panel envelope is illustrated. Two sheets of barrier film 20a and 20b have been attached face to face, conveniently by heat welding, to form vacuum insulation panel envelope 102. Within the envelope 102, is a core 104, seen in outline in this view. The core 104 is vacuum sealed within envelope 102.

### Substrates

The substrate 22 is conveniently a polymeric layer. While diverse polymers may be used, when the barrier film is used for vacuum insulation panels, puncture resistance and thermal stability are properties to be particularly prized. Examples of useful polymeric puncture resistant films include polymers such as polyethylene (PE), polyethylene terephthalate (PET), polypropylene (PP), polyethylene napthalate (PEN), polyether sulfone (PES), polycarbonate, polyestercarbonate, polyetherimide (PEI), polyarylate (PAR), polymers with trade name ARTON (available from the Japanese Synthetic Rubber Co., Tokyo, Japan), polymers with trade name AVATREL (available from the B.F. Goodrich Co., Brecksville, Ohio), polyethylene-2,6-naphthalate, polyvinylidene difluoride, polyphenylene oxide, polyphenylene sulfide, polyvinyl chloride (PVC), and ethylene vinyl alcohol (EVOH). Also useful are the thermoset polymers such as polyimide, polyimide benzoxazole, polybenzoaxozole and cellulose derivatives. Polyethylene terephthalate (PET) with a thickness of approximately 0.002 inch (0.05 mm) is considered a convenient choice, as is biaxially oriented polypropylene (BOPP) film. Biaxially oriented polypropylene (BOPP) is commercially available from several suppliers including: ExxonMobil Chemical Company of Houston, Tex.; Continental Polymers of Swindon, UK; Kaisers International Corporation of Taipei City, Taiwan and PT Indopoly Swakarsa Industry (ISI) of Jakarta, Indonesia. Other examples of suitable film material are taught in WO 02/11978, titled “Cloth-like Polymeric Films,” (Jackson et al.). In some embodiments, the substrate may be a lamination of two or more polymeric layers.

### Low Thermal Conductivity Organic Layer

When the low thermal conductivity organic layer 32 is to be formed by flash evaporation of the monomer, vapor deposition, followed by crosslinking, volatilizable acrylate and methacrylate (referred to herein as “(meth)acrylate”) monomers are useful, with volatilizable acrylate monomers being preferred. A suitable (meth)acrylate monomer has sufficient vapor pressure to be evaporated in an evaporator and condensed into a liquid or solid coating in a vapor coater.

Examples of suitable monomers include, but are not limited to, hexadiol diacrylate; ethoxyethyl acrylate; cyanoethyl (mono)acrylate; isobornyl (meth)acrylate; octadecyl acrylate; isodecyl acrylate; lauryl acrylate; beta-carboxyethyl acrylate; tetrahydrofurfuryl acrylate; dinitrile acrylate; pentafluorophenyl acrylate; nitrophenyl acrylate; 2-phenoxyethyl (meth)acrylate; 2,2,2-trifluoromethyl (meth)acrylate; diethylene glycol diacrylate; triethylene glycol di(meth)acrylate; tripropylene glycol diacrylate; tetraethylene glycol diacrylate; neo-pentyl glycol diacrylate; propoxylated neopentyl glycol diacrylate; polyethylene glycol diacrylate; tetraethylene glycol diacrylate; bisphenol A epoxy diacrylate; 1,6-hexanediol dimethacrylate; trimethylol propane triacrylate; ethoxylated trimethylol propane triacrylate; propylated trimethylol propane triacrylate; tris(2-hydroxyethyl)-isocyanurate triacrylate; pentaerythritol triacrylate; phenylthioethyl acrylate; naphthloxyethyl acrylate; epoxy acrylate under the product number RDX80094 (available from RadCure Corp., Fairfield, N.J.); and mixtures thereof. A variety of other curable materials can be included in the polymer layer, such as, e.g., vinyl ethers, vinyl mapthalene, acrylonitrile, and mixtures thereof.

In particular, tricyclodecane dimethanol diacrylate is considered suitable. It is conveniently applied by, e.g., condensed organic coating followed by UV, electron beam, or plasma initiated free radical vinyl polymerization. A thickness between about 250 and 1500 nm is considered convenient, with approximately 750 nm in thickness being considered particularly suitable.

### Low Thermal Conductivity Non-Metallic Inorganic Material Layer

The low thermal conductivity non-metallic inorganic material layer 44 may conveniently be formed of metal oxides, metal nitrides, metal oxy-nitrides, and metal alloys of oxides, nitrides and oxy-nitrides. In one aspect the low thermal conductivity non-metallic inorganic material layer 44 comprises a metal oxide. Preferred metal oxides include aluminum oxide, silicon oxide, silicon aluminum oxide, aluminum-silicon-nitride, and aluminum-silicon-oxy-nitride, CuO, TiO₂, ITO, Si₃N₄, TiN, ZnO, aluminum zinc oxide, ZrO₂, and yttria-stabilized zirconia. The use of Ca₂SiO₄ is contemplated due to its flame retardant properties. The low thermal conductivity non-metallic inorganic material 44 may be prepared by a variety of methods, such as those described in U.S. Pat. No. 5,725,909 (Shaw et al.) and U.S. Pat. No. 5,440,446 (Shaw et al.), the disclosures of which are incorporated by reference. Low thermal conductivity non-metallic inorganic material can typically be prepared by reactive evaporation, reactive sputtering, chemical vapor deposition, plasma enhanced chemical vapor deposition, and atomic layer deposition. Preferred methods include vacuum preparations such as reactive sputtering and plasma enhanced chemical vapor deposition.

The low thermal conductivity non-metallic inorganic material is conveniently applied as a thin layer. The low thermal conductivity non-metallic inorganic material, e.g. silicon aluminum oxide, can for example, provide good barrier properties, as well as good interfacial adhesion to low thermal conductivity organic layer 30. Such layers are conveniently applied by sputtering, and a thickness between about 5 and 100 nm is considered convenient, with approximately 20 nm in thickness being considered particularly suitable.

### High Electrical Conductivity Metallic Material Layer

High electrical conductivity metallic material useful, for example, in the high electrical conductivity metallic material layer 46, can include aluminum, silver, gold, copper, beryllium, tungsten, magnesium, rhodium, iridium, molybdenum, zinc, bronze, or combinations of the same. In some embodiments, the high electrical conductivity metallic material can be copper. The high electrical conductivity metallic material, e.g. copper, can for example, provide good electromagnetic shielding properties, as well as good antistatic properties. The high electrical conductivity metal may also has a high thermal conductivity, for example, a thermal conductivity of more than 1, 1.1, 1.2, 1.5, 2, 3, or 4 W/(cm·K). The metal is deposited at a thickness between about 2 and 100 nm to provide a high thermal resistance in the plane of the layer. In some embodiments, the metal can be deposited at a thickness between about 5 and 100 nm. In some embodiments, the metal can be deposited at a thickness between about 10 and 50 nm. In some embodiments, the metal can be deposited at a thickness between about 10 and 30 nm. In some embodiments, it may be convenient to partially oxidize the high electrical conductivity metallic material.

### Core

Referring again to FIG. 2, in some embodiments, vacuum insulation panel 100 includes a core 104, conveniently in the form of a rigid foam having small open cells, for example on the order of four microns in size. One source for the microporous foam core is Dow Chemical Company of Midland, Mich. In some embodiments, parallel spaced evacuation passages or grooves are cut or formed in the face of the core. Information on how the core may be vacuum sealed within the envelope is disclosed in U.S. Pat. No. 6,106,449 (Wynne), herein incorporated by reference. Other useful materials include fumed silica, glass fiber, and aerogels.

### Heat Seal Layer

An optional heat seal layer may also be present. Polyethylene, or a blend of linear low-density polyethylene and low-density polyethylene, are considered suitable. A heat seal layer may be applied to the barrier film by extrusion, coating, or lamination. A co-extruded composite layer comprising a high-density polyethylene is also considered suitable.

### Fire Retardant Layer

It may be convenient that the envelope have fire retardant properties. For example, the substrate may itself comprise a flame retardant material, or a separate flame retardant layer may be positioned in direct contact with an opposing major surface of the substrate opposite the first layer. Information on fire retardant materials suitable for use in layered products is found in U.S. Patent Application 2012/0164442 (Ong et al.), which is herein incorporated by reference.

### Properties

It may be convenient that the barrier film, or moisture barrier bag or VIP employing the barrier film is semitransparent. For example, a semitransparent barrier film allows for direct reading of a barcoded part through the barrier film using a barcode scanner and this may eliminate the need for barcoding the bag. Such semitransparent barrier film can be used in moisture barrier bags for inspection of parts or desiccant and humidity indicating card inside these bags.

In some embodiments, the barrier film, or moisture barrier bag or VIP employing the barrier film has a Rs of less than 50, 40, 30, 20, 15, 10 or 5 Ohms/sq. In some embodiments, the barrier film, or moisture barrier bag or VIP employing the barrier film has an electrostatic shielding of less than 10, 7, 5, or 3 nanoJoules. In general, the barrier film having a Rs of less than 50 Ohms/sq or an electrostatic shielding of less than 10 nanoJoules can have good electromagnetic shielding properties.

In some embodiments, the barrier film, or moisture barrier bag or VIP employing the barrier film has a static decay time of less than 2, 1 or 0.5 seconds. In general, such a static decay time can contribute to good antistatic properties of the film.

The barrier film, or moisture barrier bag or VIP employing the barrier film can have a water vapor transmission rate of less than 0.2, 0.1, 0.05 or 0.01 g/m²/day, thus providing good barrier properties.

The following embodiments are intended to be illustrative of the present disclosure and not limiting.

### EMBODIMENTS

The following working examples are intended to be illustrative of the present disclosure and not limiting.

1. A barrier film comprising:
(a) a substrate having two opposing major surfaces;
(b) a first layer in direct contact with one of the opposing major surfaces of the substrate, wherein the first layer is an inorganic stack or a low thermal conductivity organic layer or; and
(c) a second layer in direct contact with the first layer, wherein the second layer is an inorganic stack or a low thermal conductivity organic layer, and wherein the second layer is not the same as that selected in the first layer;
wherein the inorganic stack comprises a low thermal conductivity non-metallic inorganic material layer and a high electrical conductivity metallic material layer having a high thermal resistance in the plane of the high electrical conductivity metallic material layer; wherein the barrier film is semitransparent.
   2. The barrier film of embodiment 1, wherein the high electrical conductivity metallic material layer comprises a high electrical conductivity metallic material.
   3. The barrier film of embodiment 2, wherein the high electrical conductivity metallic material has an electrical conductivity of more than 1.5×10⁷ Siemens/m.
   4. The barrier film of embodiment 3, the high electrical conductivity metallic material are selected from at least one of aluminum, silver, gold, copper, beryllium, tungsten, magnesium, rhodium, iridium, molybdenum, zinc, bronze, or combinations of the same.
   5. The barrier film of any one of embodiments 1 to 4, wherein the low thermal conductivity non-metallic inorganic material layer comprises a low thermal conductivity non-metallic inorganic material and the low thermal conductivity non-metallic inorganic material is selected from at least one of aluminum oxide, silicon oxide, aluminum-silicon-oxide, aluminum-silicon-nitride, and aluminum-silicon-oxy-nitride CuO, TiO₂, ITO, Si₃N₄, TiN, ZnO, aluminum zinc oxide, ZrO₂, yttria-stabilized zirconia and Ca₂SiO₄.
   6. The barrier film of any one of the preceding embodiments, further comprising an additional low thermal conductivity organic layer.
   7. The barrier film of any one of the preceding embodiments, further comprising a flame retardant layer in direct contact with an opposing major surface of the substrate opposite the first layer.
   8. The barrier film of any one of the preceding embodiments, wherein the barrier film has a Rs of less than 50 Ohms/sq.
   9. The barrier film of any one of the preceding embodiments, wherein the barrier film has a static decay time of less than 2 seconds.
   10. The barrier film of any one of the preceding embodiments, wherein the barrier film has an electrostatic shielding of less than 10 nanoJoules.
   11. The barrier film of any one of the preceding embodiments, wherein the barrier film has a water vapor transmission rate of less than 0.031 g/m²/day.
   12. An article comprising a vacuum insulation panel envelope comprising:
(a) a substrate having two opposing major surfaces;
(b) a first layer in direct contact with one of the opposing major surfaces of the substrate, wherein the first layer is an inorganic stack or a low thermal conductivity organic layer or; and
(c) a second layer in direct contact with the first layer, wherein the second layer is an inorganic stack or a low thermal conductivity organic layer, and wherein the second layer is not the same as that selected in the first layer;
wherein the inorganic stack comprises a low thermal conductivity non-metallic inorganic material layer and a high electrical conductivity metallic material layer having a high thermal resistance in the plane of the high electrical conductivity metallic material layer.
   13. The article of embodiment 12, wherein the high electrical conductivity metallic material layer comprises a high electrical conductivity metallic material.
   14. The article of embodiment 13, the high electrical conductivity metallic material has an electrical conductivity of more than 1.5×10⁷ Siemens/m.
   15. The article of embodiment 14, the high electrical conductivity metallic material are selected from at least one of aluminum, silver, gold, copper, beryllium, tungsten, magnesium, rhodium, iridium, molybdenum, zinc, bronze, or combinations of the same.
   16. The article of any one of embodiments 11 to 15, wherein the low thermal conductivity non-metallic inorganic material layer comprises a low thermal conductivity non-metallic inorganic material and the low thermal conductivity non-metallic inorganic material is selected from at least one of aluminum oxide, silicon oxide, aluminum-silicon-oxide, aluminum-silicon-nitride, and aluminum-silicon-oxy-nitride CuO, TiO₂, ITO, Si₃N₄, TiN, ZnO, aluminum zinc oxide, ZrO₂, yttria-stabilized zirconia and Ca₂SiO₄.
   17. The article of any one of embodiments 11 to 16, further comprising an additional low conductivity organic layer.
   18. The article of any one of embodiments 11 to 17, further comprising a heat seal layer.
   19. The article of any one of embodiments 11 to 18, wherein the substrate comprises a flame retardant material.
   20. The article of any one of embodiments 11 to 19, further comprising a flame retardant layer in direct contact with an opposing major surface of the substrate opposite the first layer.
   21. The article of any one of embodiments 11 to 20, wherein the vacuum insulation panel envelope further comprises a core layer.
   22. The article of any one of embodiments 11 to 21, wherein the vacuum insulation panel envelope has a Rs of less than 50 Ohms/sq.
   23. The article of any one of embodiments 11 to 22, wherein the vacuum insulation panel envelope has an electrostatic shielding of less than 10 nanoJoules.
   24. An article comprising a moisture barrier bag comprising:
(a) a substrate having two opposing major surfaces;
(b) a first layer in direct contact with one of the opposing major surfaces of the substrate, wherein the first layer is an inorganic stack or a low thermal conductivity organic layer or; and
(c) a second layer in direct contact with the first layer, wherein the second layer is an inorganic stack or a low thermal conductivity organic layer, and wherein the second layer is not the same as that selected in the first layer;
wherein the inorganic stack comprises a low thermal conductivity non-metallic inorganic material layer and a high electrical conductivity metallic material layer having a high thermal resistance in the plane of the high electrical conductivity metallic material layer; wherein the barrier film is semitransparent.
   25. The article of embodiment 24, wherein the moisture barrier bag has a static decay time of less than 2 seconds

### EXAMPLES

All references and publications cited herein are expressly incorporated herein by reference in their entirety into this disclosure. Illustrative embodiments of this invention are discussed and reference has been made to possible variations within the scope of this invention. For example, features depicted in connection with one illustrative embodiment may be used in connection with other embodiments of the invention. These and other variations and modifications in the invention will be apparent to those skilled in the art without departing from the scope of the invention, and it should be understood that this invention is not limited to the illustrative embodiments set forth herein. Accordingly, the invention is to be limited only by the claims provided below and equivalents thereof.

### Test Methods

### Water Vapor Transmission Rate (WVTR)

Some of the following Examples were tested for barrier properties on a vapor transmission testing commercially available as PERMATRAN W700 from Mocon of Minneapolis, Minn. The testing regime was 50° C. and 100% RH.

### Visible Light Transmission (% T)

Some of the examples were measured for average visible light transmission. The % light transmitted was measured using a commercially available spectrophotometer instrument either a Lambda 950 from Perkin Elmer of Altham, Mass. or a UltraScan PRO by HunterLab of Reson, Va. The average value of the % light transmitted from 400 nm to 700 nm was calculated.

### Static Decay

Some of the following examples were tested for static decay on commercially available measurement equipment—model 406C by Electro-Tech Systems Inc of Glenside Pa.

### Sheet Resistance Rs

Some of the examples were tested for sheet resistance on commercially available non contact eddy current measurement equipment—model 717 Conductance monitor by Delcom Instruments Inc of Prescott, Wis.

### Electrostatic Shielding Tested

Some of the examples were tested for electrostatic shielding per ANSI/ESD S11.31 on commercially available equipment—model 4431T by Electro-Tech Systems Inc of Glenside Pa.

### EXAMPLES

### Example 1

The following Examples of barrier films were made on a vacuum coater similar to the coater described in U.S. Pat. No. 5,440,446 (Shaw et al.) and U.S. Pat. No. 7,018,713 (Padiyath, et al.). This coater was threaded up with a substrate in the form of an indefinite length roll of 0.05 mm thick, 14 inch (35.6 cm) wide PET film commercially available from DuPont-Teijin Films of Chester, Va. This substrate was then advanced at a constant line speed of 16 fpm (4.9 m/min). The substrate was prepared for coating by subjecting it to a nitrogen plasma treatment to improve the adhesion of the low thermal conductivity organic layer.

A low thermal conductivity organic layer was formed on the substrate by applying tricyclodecane dimethanol diacrylate, commercially available as SARTOMER SR833S from Sartomer USA of Exton, Pa., by ultrasonic atomization and flash evaporation to make a coating width of 12.5 inches (31.8 cm). This monomeric coating was subsequently cured immediately downstream with an electron beam curing gun operating at 7.0 kV and 4.0 mA. The flow of liquid into the evaporator was 1.33 ml/min, the gas flow rate was 60 sccm and the evaporator temperature was set at 260° C. The process drum temperature was −10° C.

On top of this low thermal conductivity organic layer, the inorganic stack was applied, starting with the high electrical conductivity metallic inorganic material. More specifically, a conventional AC sputtering process operated at 4 kW of power was employed to deposit a 15 nm thick layer of copper onto the now polymerized low thermal conductivity organic layer (the book value of the electrical conductivity is 5.96×10⁷ Siemens/m and the book value of the thermal conductivity of copper is 4.0 W/(cm·K)). Then a low thermal conductivity non-metallic inorganic material was laid down by an AC reactive sputter deposition process employing a 40 kHz AC power supply. The cathode had a Si(90%)/Al(10%) target obtained from Soleras Advanced Coatings US, of Biddeford, (ME). The voltage for the cathode during sputtering was controlled by a feed-back control loop that monitored the voltage and controlled the oxygen flow such that the voltage would remain high and not crash the target voltage. The system was operated at 16 kW of power to deposit a 20 nm thick layer of silicon aluminum oxide onto the copper layer.

A further in-line process was used to deposit a second polymeric layer on top of the silicon aluminum oxide layer. This polymeric layer was produced from monomer solution by atomization and evaporation. However, the material applied to form this top layer was a mixture of 3 wt % (N-(n-butyl)-3-aminopropyltrimethoxysilane commercially available as DYNASILAN 1189 from Evonik of Essen, Del.; 1 wt % 1-hydroxy-cyclohexyl-phenyl-ketone commercially available as IRGACURE 184 from BASF of Ludwigshafen, Del.; with the remainder SARTOMER SR833S. The flow rate of this mixture into the atomizer was 1.33 ml/min, the gas flow rate was 60 sccm, and the evaporator temperature was 260° C. Once condensed onto the silicon aluminum oxide layer, the coated mixture was cured to a finished polymer with an UV light.

It was tested for water vapor transmission according to the test method discussed above. The water vapor transmission rate in this experiment was found to be below the detection limit for the apparatus.

### Example 2

A barrier film was prepared according to the procedure of Example 1, except that the substrate was a 2.15 mil thick biaxially oriented polypropylene. It was tested for water vapor transmission according to the test method discussed above, and the water vapor transmission rate was found to be below the detection limit for the apparatus.

### Example 3

The following Examples of barrier films were made on a vacuum coater similar to the coater described in U.S. Pat. No. 5,440,446 (Shaw et al.) and U.S. Pat. No. 7,018,713 (Padiyath, et al.). This coater was threaded up with a substrate in the form of an indefinite length roll of 0.00092 inch (0.023 mm) thick PET film commercially available as Astroll ST01 from Kolon Industries Inc. of Gwacheon-si, Korea. This substrate was then advanced at a constant line speed of 16 fpm (4.9 m/min). The substrate was prepared for coating by subjecting it to a nitrogen plasma treatment to improve the adhesion of the low thermal conductivity organic layer.

A low thermal conductivity organic layer was formed on the substrate by applying tricyclodecane dimethanol diacrylate, commercially available as SARTOMER SR833S from Sartomer USA of Exton, Pa., by ultrasonic atomization and flash evaporation to make a coating width of 12.5 inches (31.8 cm). This monomeric coating was subsequently cured immediately downstream with an electron beam curing gun operating at 7.0 kV and 4.0 mA. The flow of liquid into the evaporator was 1.33 ml/min, the gas flow rate was 60 sccm and the evaporator temperature was set at 260° C. The process drum temperature was −10° C.

On top of this low thermal conductivity organic layer, the inorganic stack was applied, starting with the high electrical conductivity metallic inorganic material. More specifically, two cathodes using a conventional DC sputtering process operated at 2.8 kW of power for each cathode was employed to deposit a 35 nm thick layer of copper onto the now polymerized low thermal conductivity organic layer (the book value of the electrical conductivity is 5.96×10⁷ Siemens/m and the book value of the thermal conductivity of copper is 4.0 W/(cm·K)). Then a low thermal conductivity non-metallic inorganic material was laid down by an AC reactive sputter deposition process employing a 40 kHz AC power supply. The cathode had a Si(90%)/Al(10%) target obtained from Soleras Advanced Coatings US, of Biddeford, (ME). The voltage for the cathode during sputtering was controlled by a feed-back control loop that monitored the voltage and controlled the oxygen flow such that the voltage would remain high and not crash the target voltage. The system was operated at 16 kW of power to deposit a 20 nm thick layer of silicon aluminum oxide onto the copper layer.

A further in-line process was used to deposit a second polymeric layer on top of the silicon aluminum oxide layer. This polymeric layer was produced from monomer solution by atomization and evaporation. However, the material applied to form this top layer was a mixture of 3 wt % (N-n-butyl-AZA-2,2-dimethoxysilacyclopentane); with the remainder SARTOMER SR833S. This monomeric coating was subsequently cured immediately downstream with an electron beam curing gun operating at 7.0 kV and 10.0 mA. The flow rate of this mixture into the atomizer was 1.33 ml/min, the gas flow rate was 60 sccm, and the evaporator temperature was 260° C.

### Example 4

A barrier film was prepared generally according to the procedure of Example 3, except for the following particulars. The power to each cathode used to deposit copper was 4.0 kW to deposit a 50 nm thick layer of copper.

### Example 5

A barrier film was prepared generally according to the procedure of Example 3, except for the following particulars. The substrate used was 0.97 mil PET commercially available from Toray Plastics America and the power to each cathode used to deposit copper was 0.8 kW to deposit a 10 nm thick layer of copper.

### Example 6

A barrier film was prepared generally according to the procedure of Example 5, except for the following particulars. The cathode using the SiAl target had 80 sccm of N2 flowed in the AC reactive sputtering process to deposit 20 nm of silicon aluminum oxy nitride.

### Example 7

A barrier film was prepared generally according to the procedure of Example 5, except for the following particulars. The flow of liquid into the evaporator was 2.66 ml/min when the low thermal conductivity organic layer was formed on the substrate.

The results of static decay, Electrostatic shielding, transparency, Rs and WVTR are presented in Table 1 below.

TABLE 1

| | Static | | | | |
|---|---|---|---|---|---|
| | decay | Electrostatic | | | |
| Example | (sec) | shielding (nJ) | % T (avg 400-700 nm) | Rs (ohms/sq) | WVTR (g/m2/day) |
| 1 | <0.01 | | 46.3 | 7.8 | Below detection |
| 2 | | | | | Below detection |
| 3 | <0.01 | below detection | 33.1 | 4.3 | |
| 4 | <0.01 | | 20.6 | 2.6 | Below detection |
| 5 | | | 65.6 | 12.7 | |
| 6 | | | 65.6 | 14.9 | |
| 7 | 0.01 | | 68.4 | 50 | 0.007 |

1. A barrier film comprising:
(a) a substrate having two opposing major surfaces;
(b) a first layer in direct contact with one of the opposing major surfaces of the substrate, wherein the first layer is an inorganic stack or a low thermal conductivity organic layer or; and
(c) a second layer in direct contact with the first layer, wherein the second layer is an inorganic stack or a low thermal conductivity organic layer, and wherein the second layer is not the same as that selected in the first layer;
wherein the inorganic stack comprises a low thermal conductivity non-metallic inorganic material layer and a high electrical conductivity metallic material layer having a high thermal resistance in the plane of the high electrical conductivity metallic material layer;
wherein the barrier film is semitransparent.

2. The barrier film of claim 1, wherein the high electrical conductivity metallic material layer comprises a high electrical conductivity metallic material.

3. The barrier film of claim 2, wherein the high electrical conductivity metallic material has an electrical conductivity of more than 1.5×10⁷ Siemens/m

4. The barrier film of claim 3, the high electrical conductivity metallic material are selected from at least one of aluminum, silver, gold, copper, beryllium, tungsten, magnesium, rhodium, iridium, molybdenum, zinc, bronze, or combinations of the same.

5. The barrier film of claim 1, wherein the low thermal conductivity non-metallic inorganic material layer comprises a low thermal conductivity non-metallic inorganic material and the low thermal conductivity non-metallic inorganic material is selected from at least one of aluminum oxide, silicon oxide, aluminum-silicon-oxide, aluminum-silicon-nitride, and aluminum-silicon-oxy-nitride CuO, TiO₂, ITO, Si₃N₄, TiN, ZnO, aluminum zinc oxide, ZrO₂, yttria-stabilized zirconia and Ca₂SiO₄.

6. The barrier film of claim 1, further comprising an additional low thermal conductivity organic layer.

7. The barrier film of claim 1, further comprising a flame retardant layer in direct contact with an opposing major surface of the substrate opposite the first layer.

8. The barrier film of claim 1, wherein the barrier film has a Rs of less than 50 Ohms/sq.

9. The barrier film of claim 1, wherein the barrier film has a static decay time of less than 2 seconds.

10. The barrier film of claim 1, wherein the barrier film has an electrostatic shielding of less than 10 nanoJoules.

11. The barrier film of claim 1, wherein the barrier film has a water vapor transmission rate of less than 0.031 g/m²/day.

12. An article comprising a vacuum insulation panel envelope comprising:
(a) a substrate having two opposing major surfaces;
(b) a first layer in direct contact with one of the opposing major surfaces of the substrate, wherein the first layer is an inorganic stack or a low thermal conductivity organic layer or; and
(c) a second layer in direct contact with the first layer, wherein the second layer is an inorganic stack or a low thermal conductivity organic layer, and wherein the second layer is not the same as that selected in the first layer;
wherein the inorganic stack comprises a low thermal conductivity non-metallic inorganic material layer and a high electrical conductivity metallic material layer having a high thermal resistance in the plane of the high electrical conductivity metallic material layer.

13-18. (canceled)

19. The article of claim 11, wherein the substrate comprises a flame retardant material.

20. The article of claim 11, further comprising a flame retardant layer in direct contact with an opposing major surface of the substrate opposite the first layer.

21. The article of claim 11, wherein the vacuum insulation panel envelope further comprises a core layer.

22. The article of claim 11, wherein the vacuum insulation panel envelope has a moisture vapor transmission rate of less than 0.2 g/m²/day.

23. The article of claim 11, wherein the vacuum insulation panel envelope has an electrostatic shielding of less than 10 nanoJoules.

24. An article comprising a moisture barrier bag comprising:
(a) a substrate having two opposing major surfaces;
(b) a first layer in direct contact with one of the opposing major surfaces of the substrate, wherein the first layer is an inorganic stack or a low thermal conductivity organic layer or; and
(c) a second layer in direct contact with the first layer, wherein the second layer is an inorganic stack or a low thermal conductivity organic layer, and wherein the second layer is not the same as that selected in the first layer;
wherein the inorganic stack comprises a low thermal conductivity non-metallic inorganic material layer and a high electrical conductivity metallic material layer having a high thermal resistance in the plane of the high electrical conductivity metallic material layer;
wherein the barrier film is semitransparent.

25. The article of claim 24, wherein the moisture barrier bag has a static decay time of less than 2 seconds
